(19) United States
(12) Patent Application Publication
(10) Pub. No.: US 2025/0324890 A1
(43) Pub. Date: Oct. 16, 2025

(54) METHOD OF MANUFACTURING AN ADHESIVE MEMBER, AN ADHESIVE MEMBER MANUFACTURED THEREBY, A DISPLAY DEVICE INCLUDING THE ADHESIVE MEMBER, AND AN ELECTRONIC DEVICE INCLUDING THE DISPLAY DEVICE

(71) Applicant: SAMSUNG DISPLAY CO., LTD., YONGIN-SI (KR)

(72) Inventors: ONNURI KIM, Yongin-si (KR); SEOHYEON CHOI, Yongin-si (KR); YEJIN KIM, Yongin-si (KR); SANG-GU LEE, Yongin-si (KR)

(21) Appl. No.: 19/042,107

(22) Filed: Jan. 31, 2025

(30) Foreign Application Priority Data
Apr. 15, 2024 (KR) 10-2024-0049892

(51) Int. Cl. H10K 59/80; H10K 59/12

(52) U.S. Cl. CPC H10K 59/873; H10K 59/1201

(57) ABSTRACT

A method of manufacturing an adhesive member includes applying a first resin composition on a base material to form a first preliminary layer. The first preliminary layer is photocured to form a first cured layer. A second resin composition is applied on the first cured layer to form a second preliminary layer. The second preliminary layer is photocured to form a second cured layer. A contact angle of a surface of the first cured layer with respect to the second resin composition is greater than or equal to about 30 degrees.

### CROSS-REFERENCE TO RELATED APPLICATION

This application claims priority under 35 U.S.C. § 119 to Korean Patent Application No. 10-2024-0049892, filed on Apr. 15, 2024 in the Korean Intellectual Property Office, the disclosure of which is incorporated by reference in its entirety herein.

### 1. Technical Field

Embodiments of the present disclosure relate to a method of manufacturing an adhesive member. More particularly, embodiments of the present disclosure relate to a method of manufacturing the adhesive member, the adhesive member manufactured by the method, and a display device including the adhesive member.

### 2. Discussion of Related Art

A display device is an electronic device that generates images and serves as a connecting medium between users and visual information. The importance of display devices to consumers has increased along with the development of the information society. Some of the components included in the display device may be coupled to each other through an adhesive member. Research is being conducted to increase the reliability of the adhesive member to prevent the visibility of the display device from deteriorating and to reduce the size of a dead space.

### SUMMARY

Embodiments of the present disclosure provide a method of manufacturing an adhesive member with increased reliability.

Embodiments of the present disclosure provide the adhesive member manufactured by the method of manufacturing the adhesive member.

Embodiments of the present disclosure provide a display device including the adhesive member.

According to an embodiment of the present disclosure, a method of manufacturing an adhesive member includes applying a first resin composition on a base material to form a first preliminary layer. The first preliminary layer is photocured to form a first cured layer. A second resin composition is applied on the first cured layer to form a second preliminary layer. The second preliminary layer is photocured to form a second cured layer. A contact angle of a surface of the first cured layer with respect to the second resin composition is greater than or equal to about 30 degrees.

In an embodiment, a surface energy of the first cured layer may be less than or equal to about 45 mJ/m².

In an embodiment, a viscosity of the first resin composition may be in a range of about 5 cP to about 40 cP.

In an embodiment, the second preliminary layer may have an inclined portion having a thickness becoming thinner towards an edge of the second preliminary layer, and a length in a horizontal direction from a point where the inclined portion of the second preliminary layer starts to the edge of the second preliminary layer may be less than or equal to about 2 mm. In an embodiment, the first resin composition may be first applied on the base material through an inkjet printing process, and the second resin composition may be subsequently applied on the first cured layer through the inkjet printing process.

In an embodiment, in the forming of the adhesive member, the first cured layer may be cured to form a first adhesive layer disposed on the base material, and the second cured layer may be cured to form a second adhesive layer selectively disposed on an outer portion of the first adhesive layer.

In an embodiment, in the forming of the first cured layer, a curing rate of the first cured layer by photocuring may be in a range of about 35% to about 50%.

In an embodiment, the first resin composition may include a contact angle regulator.

In an embodiment, the first resin composition and the second resin composition may be a same composition as each other.

According to an embodiment of the present disclosure, an adhesive member includes a first adhesive layer including a first adhesive composition derived from a first resin composition that includes a photoinitiator. A second adhesive layer is disposed on the first adhesive layer. The second adhesive layer includes a second adhesive composition derived from a second resin composition that includes a photoinitiator. A contact angle of a surface of a cured layer obtained by photocuring the first resin composition at a curing rate in a range of about 35% to about 50% with respect to the second resin composition is greater than or equal to about 30 degrees.

In an embodiment, a surface energy of the cured layer may be less than or equal to about 45 mJ/m².

In an embodiment, the first adhesive layer may have a first outer portion having a thickness becoming thinner towards an edge of the first adhesive layer. The second adhesive layer may have a second outer portion having a thickness that becomes thinner towards an edge of the second adhesive layer. The second adhesive layer may be selectively disposed on the first outer portion of the first adhesive layer. A length in a horizontal direction from a point where the second outer portion of the second adhesive layer starts to the edge of the second adhesive layer may be less than or equal to about 1 mm.

In an embodiment, the first adhesive layer may include a contact angle regulator.

According to an embodiment of the present disclosure, a display device includes a display panel including a display area and a peripheral area surrounding the display area. A window member is disposed on the display panel. A first adhesive layer is disposed between the display panel and the window member. The first adhesive layer overlaps the display area and the peripheral area. The first adhesive layer includes a first adhesive composition derived from a first resin composition including a photoinitiator. A second adhesive layer is disposed on the first adhesive layer. The second adhesive layer overlaps the peripheral area. The second adhesive layer includes a second adhesive composition derived from a second resin composition including a photoinitiator. A contact angle of a surface of a cured layer obtained by photocuring the first resin composition at a curing rate in a range of about 35% to about 50% with respect to the second resin composition is greater than or equal to about 30 degrees.

In an embodiment, a surface energy of the cured layer may be less than or equal to about 45 mJ/m².

In an embodiment, the first adhesive layer may have a first outer portion having a thickness becoming thinner towards an edge of the first adhesive layer. The second adhesive layer may have a second outer portion having a thickness becoming thinner towards an edge of the second adhesive layer.

In an embodiment, a length in a horizontal direction from a point where the second outer portion of the second adhesive layer starts to the edge of the second adhesive layer may be less than or equal to about 1 mm.

In an embodiment, the second adhesive layer may be selectively disposed on the first outer portion of the first adhesive layer.

In an embodiment, the first adhesive layer may include a contact angle regulator.

In an embodiment, the first resin composition and the second resin composition may be a same composition as each other.

According to an embodiment of the present disclosure, an electronic device includes a display device and a processor which controls the display device. A display device includes a display panel including a display area and a peripheral area surrounding the display area. A window member is disposed on the display panel. A first adhesive layer is disposed between the display panel and the window member. The first adhesive layer overlaps the display area and the peripheral area. The first adhesive layer includes a first adhesive composition derived from a first resin composition including a photoinitiator. A second adhesive layer is disposed on the first adhesive layer. The second adhesive layer overlaps the peripheral area. The second adhesive layer includes a second adhesive composition derived from a second resin composition including a photoinitiator. A contact angle of a surface of a cured layer obtained by photocuring the first resin composition at a curing rate in a range of about 35% to about 50% with respect to the second resin composition is greater than or equal to about 30 degrees.

In a method of manufacturing an adhesive member according to some embodiments of the present disclosure, the adhesive member may be formed to include a first adhesive layer and a second adhesive layer disposed on the first adhesive layer. The second adhesive layer may be formed by forming a preliminary layer by applying a second resin composition on a cured layer in which the first resin composition has been cured at a curing rate in a range of about 35% to about 50%, and photocuring the preliminary layer. In addition, a contact angle of a surface of the cured layer with respect to the second resin composition may be greater than or equal to about 30 degrees.

Accordingly, in the preliminary layer, a length in a horizontal direction of an inclined portion having a thickness gradually becoming thinner towards an edge of the preliminary layer may be reduced. As a result, a length of an inclined structure of the second adhesive layer derived from the preliminary layer in the horizontal direction may be reduced. For example, the length of the inclined structure of the second adhesive layer in the horizontal direction may be less than or equal to about 1 mm. Accordingly, in a display device including the adhesive member, the inclined structure of the second adhesive layer may not be visible from the outside, thereby increasing visibility of the display device. In addition, a dead space of the display device may be reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view taken along line I-I′ of FIG. 1 according to an embodiment of the present disclosure.

FIG. 3 is a cross-sectional view illustrating a display panel included in the display device of FIG. 2 according to an embodiment of the present disclosure.

FIG. 4 is an enlarged view illustrating an area AA of FIG. 2 according to an embodiment of the present disclosure.

FIGS. 5, 6, 7, 8, 9, 11, and 12 are views illustrating a method of manufacturing a second adhesive member of FIG. 4 according to embodiments of the present disclosure.

FIG. 13 is a block diagram illustrating an electronic device according to an embodiment of the present disclosure.

### DETAILED DESCRIPTION OF EMBODIMENTS

Hereinafter, embodiments of the present disclosure will be explained in detail with reference to the accompanying drawings. The same reference numerals are used for the same components in the drawings, and redundant descriptions of the same components may be omitted for economy of explanation.

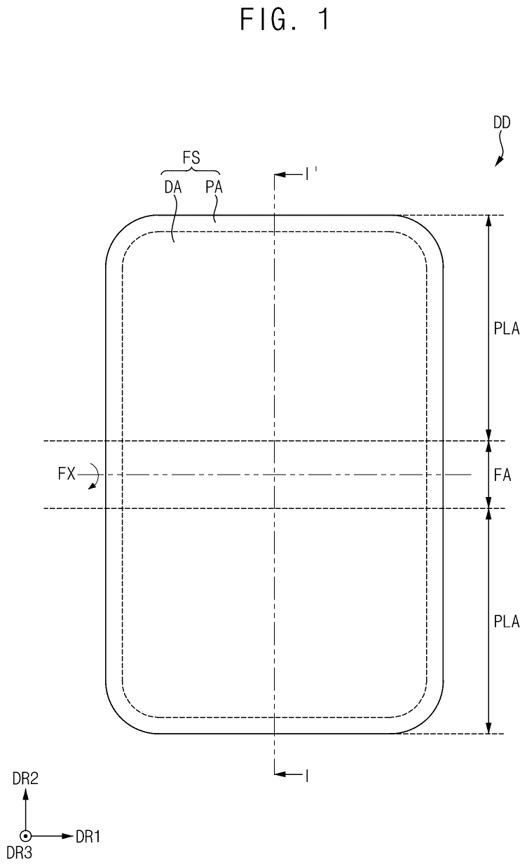

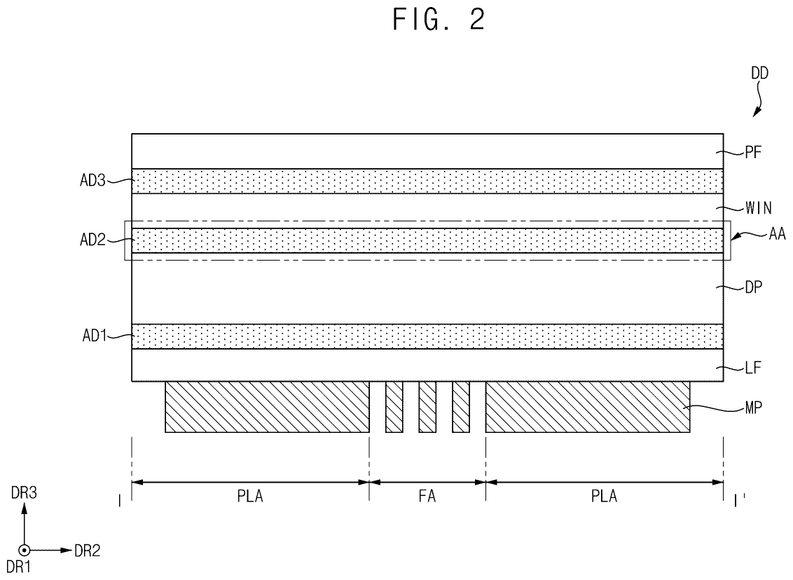

FIG. 1 is a plan view illustrating a display device according to an embodiment of the present disclosure.

Referring to FIG. 1, a display device DD according to an embodiment of the present disclosure may include a display surface FS. In an embodiment, the display surface FS may be defined in a plane extending in a first direction DR1 and a second direction DR2 crossing the first direction DR1. The display device DD may provide an image to the user through the display surface FS. For example, the display device DD may display the image in a third direction DR3 based on the display surface FS. In this specification, the front (e.g., upper) and back (e.g., lower) surfaces of each component are defined based on a direction in which the image is displayed. In an embodiment, the first to third directions DR1 to DR3 may be perpendicular to each other. However, embodiments of the present disclosure are not necessarily limited thereto and the first to third directions DR1 to DR3 may cross each other at various different angles.

The display surface FS of the display device DD may include a display area DA and a peripheral area PA. The display area DA may be an area in which images are displayed by generating light or adjusting the transmittance of light provided from an external light source. The peripheral area PA may be located around the display area DA. For example, the peripheral area PA may entirely surround the display area DA (e.g., in the first and second directions D1, D2). In an embodiment, drivers for displaying images in the display area DA may be disposed in the peripheral area PA.

A plurality of pixels may be disposed in the display area DA. In an embodiment, the pixels may be arranged in a matrix form along the first direction DR1 and the second direction DR2. An image may be displayed in the display area DA by combining the light emitted by the pixels.

In an embodiment, the display device DD may be divided into a folding area FA and a flat area PLA. For example, as shown in FIG. 1, the display device DD may include the folding area FA and the flat areas PLA adjacent to the folding area FA. For example, in an embodiment, the display device DD may including one folding area FA and two flat areas PLA adjacent to the folding area FA in the second direction DR2 and a direction opposite to the second direction DR2. However, embodiments of the present disclosure are not necessarily limited thereto. The display device DD may be folded in the folding area FA. For example, the display device DD may be folded based on a virtual folding axis FX extending from the folding area FA in the first direction DR1. The flat areas PLA may be spaced apart from each other in the second direction DR2 crossing the first direction DR1 with the folding area FA interposed therebetween. However, an extension direction of the folding axis FX is not necessarily limited to the first direction DR1.

In an embodiment, the display device DD may be in-folded based on the folding axis FX so that the flat areas PLA of the display surface FS face each other and are not exposed to the outside (e.g., the external environment). In addition, in an embodiment, the display device DD may be out-folded based on the folding axis FX so that the flat areas PLA of the display surface FS face away from each other and are exposed to the outside (e.g., the external environment).

However, the display device DD is not necessarily limited to the above configuration. For example, in an embodiment the display device DD may include a plurality of folding areas. In this embodiment, the display device DD may be in-folded in some of the folding areas and out-folded in other folding areas. In addition, the display device DD may have an asymmetric structure in which the areas of the flat areas are different from each other.

In FIG. 1, the display device DD is shown as a foldable display device that is transformed into a folded form. However, embodiments of the present disclosure are not necessarily limited to this. For example, the display device DD may be a flexible display device having a shape that may be changed by bending, rolling or otherwise deformed.

FIG. 2 is a cross-sectional view taken along line I-I′ of FIG. 1.

Referring to FIG. 2, in an embodiment the display device DD may include a display panel DP, a first adhesive member AD1, a lower film LF, a support member MP, a second adhesive member AD2, a window member WIN, a third adhesive member AD3, and a protective film PF.

The first adhesive member AD1 may be disposed under the display panel DP (e.g., directly thereunder in a direction opposite to the third direction DR3). In an embodiment, the first adhesive member AD1 may be formed of at least one of optical clear adhesive, optical clear resin, and pressure sensitive adhesive. The first adhesive member AD1 may have adhesive force.

The lower film LF may be disposed under the first adhesive member AD1 (e.g., disposed directly thereunder in a direction opposite to the third direction DR3). The lower film LF may be coupled to the display panel DP through the first adhesive member AD1. The lower film LF may absorb external shock applied to the display panel DP. In an embodiment, the lower film LF may be formed of plastic.

The support member MP may be disposed under the lower film LF (e.g., disposed directly thereunder in a direction opposite to the third direction DR3). The support member MP may support the display panel DP. In an embodiment, the support member MP may be formed of a metallic material, a non-metallic material, and the like. Examples of metal materials that can be used as the support member MP may include invar, an alloy of nickel (Ni) and iron (Fe), stainless steel (SUS), titanium (Ti), copper (Cu), aluminum (Al), and the like. An example of a non-metallic material that can be used as the support member MP may include fiber reinforced plastic (FRP). These materials can be used alone or in combination with each other. However, embodiments of the present disclosure are not necessarily limited thereto. In addition, holes overlapping the folding area FA may be defined in the support member MP. In an embodiment, each of the holes may extend (e.g., in the third direction DR3) through an entire thickness of the support member MP.

The second adhesive member AD2 may be disposed on the display panel DP (e.g., disposed directly thereon in the third direction DR3). The second adhesive member AD2 may have adhesive force. In an embodiment, the second adhesive member AD2 may be formed from a liquid optical clear resin composition. Accordingly, the second adhesive member AD2 may easily fill a step of the display panel DP and/or the window member WIN.

The window member WIN may be disposed on the second adhesive member AD2 (e.g., disposed directly thereon in the third direction DR3). The window member WIN may be coupled to the display panel DP through the second adhesive member AD2. The window member WIN may protect the display panel DP. For example, in an embodiment the window member WIN may be formed of colorless polyimide, ultra-thin tempered glass (UTG), polyethylene terephthalate (PET), polyimide (PI), polyethersulfone (PS), polyacrylate (PAR), polyetherimide (PEI), polyethylenenaphthalate (PEN), polyphenylene sulfide (PPS), polycarbonate (PC), and the like. These materials can be used alone or in combination with each other. However, embodiments of the present disclosure are not necessarily limited thereto.

The third adhesive member AD3 may be disposed on the window member WIN (e.g., disposed directly thereon in the third direction DR3). In an embodiment, the third adhesive member AD3 may be formed of at least one of optical clear adhesive, optical clear resin, and pressure sensitive adhesive. The third adhesive member AD3 may have adhesive force.

The protective film PF may be disposed on the third adhesive member AD3 (e.g., disposed directly thereon in the third direction DR3). The protective film PF may be coupled to the window member WIN through the third adhesive member AD3. The protective film PF may protect the window member WIN. In an embodiment, the protective film PF may be formed of plastic.

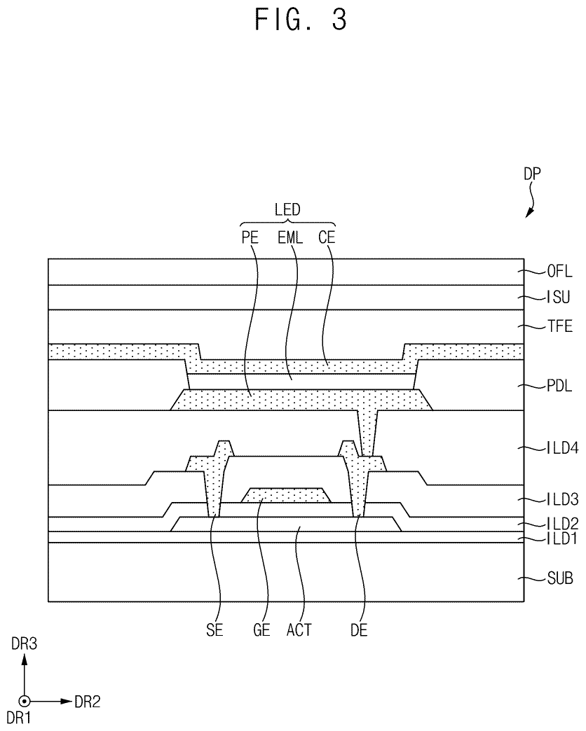

FIG. 3 is a cross-sectional view illustrating a display panel included in the display device of FIG. 2.

Referring to FIG. 3, in an embodiment the display panel DP may include a substrate SUB, an active pattern ACT, a gate electrode GE, a first connection electrode SE, a second connection electrode DE, first, second, third, and fourth insulating layer ILD1, ILD2, ILD3, and ILD4, a pixel defining layer PDL, a light emitting element LED, an encapsulation layer TFE, an input sensing layer ISU, and an optical functional layer OFL. For example, the light emitting element LED may include a pixel electrode PE, a light emitting layer EML, and a common electrode CE.

The substrate SUB may include a transparent or opaque material. In an embodiment, examples of materials that can be used as the substrate SUB may include glass, quartz, plastic, and the like. These materials can be used alone or in combination with each other. However, embodiments of the present disclosure are not necessarily limited thereto.

The first insulating layer ILD1 may be disposed on the substrate SUB (e.g., disposed directly thereon in the third direction DR3). The first insulating layer ILD1 may prevent metal atoms or impurities from diffusing from the substrate SUB to the active pattern ACT. In an embodiment, the first insulating layer ILD1 may be formed of an insulating material. In an embodiment, examples of insulating materials that can be used as the first insulating layer ILD1 may include silicon oxide, silicon nitride, silicon oxynitride, and the like. These materials can be used alone or in combination with each other. However, embodiments of the present disclosure are not necessarily limited thereto.

The active pattern ACT may be disposed on the first insulating layer ILD1 (e.g., disposed directly thereon in the third direction DR3). In an embodiment, the active pattern ACT may be formed of a silicon semiconductor material, an oxide semiconductor material, or an organic semiconductor material. The active pattern ACT may include a source region, a drain region, and a channel region located between the source region and the drain region.

The second insulating layer ILD2 may be disposed on the active pattern ACT (e.g., disposed directly thereon). The second insulating layer ILD2 may cover the active pattern ACT. In an embodiment, the second insulating layer ILD2 may be formed of an insulating material. In an embodiment, examples of insulating materials that can be used as the second insulating layer ILD2 may include silicon oxide, silicon nitride, silicon oxynitride, and the like. These materials can be used alone or in combination with each other. However, embodiments of the present disclosure are not necessarily limited thereto.

The gate electrode GE may be disposed on the second insulating layer ILD2 (e.g., disposed directly thereon in the third direction DR3). The gate electrode GE may overlap the channel area of the active pattern ACT (e.g., in the third direction DR3). In an embodiment, the gate electrode GE may be formed of metal, alloy, conductive metal oxide, transparent conductive material, and the like. However, embodiments of the present disclosure are not necessarily limited thereto. The gate electrode GE may have a single-layer structure or a multi-layer structure including a plurality of conductive layers.

The third insulating layer ILD3 may be disposed on the gate electrode GE (e.g., disposed directly thereon). The third insulating layer ILD3 may cover the gate electrode GE. In an embodiment, the third insulating layer ILD3 may be formed of an insulating material. In an embodiment, examples of insulating materials that can be used as the third insulating layer ILD3 may include silicon oxide, silicon nitride, silicon oxynitride, and the like. These materials can be used alone or in combination with each other. However, embodiments of the present disclosure are not necessarily limited thereto.

The first connection electrode SE and the second connection electrode DE may be disposed on the third interlayer insulating layer ILD3 (e.g., disposed directly thereon in the third direction DR3). In an embodiment, the first connection electrode SE and the second connection electrode DE may directly contact the source region and the drain region of the active pattern ACT, respectively. In an embodiment, the first connection electrode SE and the second connection electrode DE may be formed of metal, alloy, conductive metal oxide, transparent conductive material, and the like.

The fourth insulating layer ILD4 may be disposed on (e.g., disposed directly thereon) the first connection electrode SE and the second connection electrode DE. The fourth insulating layer ILD4 may cover the first connection electrode SE and the second connection electrode DE. The fourth insulating layer ILD4 may be formed of an insulating material. In an embodiment, examples of insulating materials that can be used as the fourth insulating layer ILD4 may include photoresist, polyacrylic resin, polyimide-based resin, polyamide-based resin, siloxane-based resin, acrylic resin, epoxy-based resin, and the like. These materials can be used alone or in combination with each other. However, embodiments of the present disclosure are not necessarily limited thereto. The fourth insulating layer ILD4 may have a single-layer structure or a multi-layer structure including a plurality of insulating layers.

The pixel electrode PE may be disposed on the fourth insulating layer ILD4 (e.g., disposed directly thereon in the third direction DR3). The pixel electrode PE may include a conductive material such as a metal, alloy, conductive metal nitride, conductive metal oxide, transparent conductive material, and the like. The pixel electrode PE may have a single-layer structure or a multi-layer structure including a plurality of conductive layers.

In an embodiment, the pixel electrode PE may be electrically connected to at least one of the first connection electrode SE and the second connection electrode DE through a contact hole formed in the fourth insulating layer ILD4.

The pixel defining layer PDL may be disposed on (e.g., disposed directly thereon) the fourth insulating layer ILD4 and the pixel electrode PE. The pixel defining layer PDL may be formed of an insulating material. In an embodiment, examples of insulating materials that can be used as the pixel defining layer PDL may include photoresist, polyacrylic resin, polyimide resin, polyamide resin, siloxane resin, acrylic resin, epoxy resin, and the like. These materials can be used alone or in combination with each other. The pixel defining layer PDL may define an opening exposing at least a portion of the pixel electrode PE. For example, in an embodiment, the pixel defining layer PDL may cover lateral sides of the pixel electrode PE and may have an opening exposing a central portion of the pixel electrode PE (e.g., in the second direction DR2).

The light emitting layer EML may be disposed on the pixel electrode PE exposed by the opening of the pixel defining layer PDL (e.g., in the third direction DR3). In an embodiment, the light emitting layer EML may have a multilayer structure including a hole injection layer, a hole transport layer, an electron transport layer, a light emitting material layer, and an electron injection layer.

The common electrode CE may be disposed on the light emitting layer EML (e.g., in the third direction DR3). The common electrode CE may include a conductive material such as a metal, alloy, conductive metal nitride, conductive metal oxide, transparent conductive material, and the like. The common electrode CE may have a single-layer structure or a multi-layer structure including a plurality of conductive layers. In an embodiment, the common electrode CE may extend continuously on the display area DA across a plurality of pixels.

The encapsulation layer TFE may be disposed on the common electrode CE (e.g., disposed directly thereon). The encapsulation layer TFE may cover the light emitting element LED. The encapsulation layer TFE may prevent impurities from penetrating into the light emitting element LED. In an embodiment, the encapsulation layer TFE may include at least one organic layer and at least one inorganic layer.

The input sensing layer ISU may be disposed on the encapsulation layer TFE (e.g., disposed directly thereon in the third direction DR3). The input sensing layer ISU may detect external input. External input may be provided in various forms. For example, in an embodiment the external input may be in the form of a user's touch, pen touch, light, heat, or pressure. In addition, the input may be in the form of a touch (e.g., hovering) in an adjacent space as well as a direct contact. The input sensing layer ISU may include at least one touch electrode and at least one insulating layer. However, embodiments of the present disclosure are not necessarily limited thereto. For example, in an embodiment, the input sensing layer ISU may be omitted.

The optical functional layer OFL may be disposed on the encapsulation layer TFE (e.g., disposed directly thereon in the third direction DR3). For example, the optical functional layer OFL may reduce the reflectance of light (e.g., external light) incident towards the display panel DP. In an embodiment, the optical functional layer OFL may include a phase retarder and a polarizer. However, embodiments of the present disclosure are not necessarily limited thereto. For example, in an embodiment the optical functional layer OFL may include a black matrix including a light blocking material and a color filter. In an embodiment, the color filter may be set considering the color of light emitted from the light emitting element LED.

In an embodiment, the optical functional layer OFL may be omitted. In an embodiment, in which the optical functional layer OFL is omitted, a polarizing layer may be additionally disposed between the display panel DP and the window member WIN of FIG. 2 (e.g., in the third direction DR3). For example, the polarizing layer may be disposed between the display panel DP and the second adhesive member AD2 (e.g., in the third direction DR3). For example, a second adhesive member AD2 may be disposed between the window member WIN and the polarizing layer (e.g., in the third direction DR3), and the window member WIN may be coupled to the polarizing layer through the second adhesive member AD2.

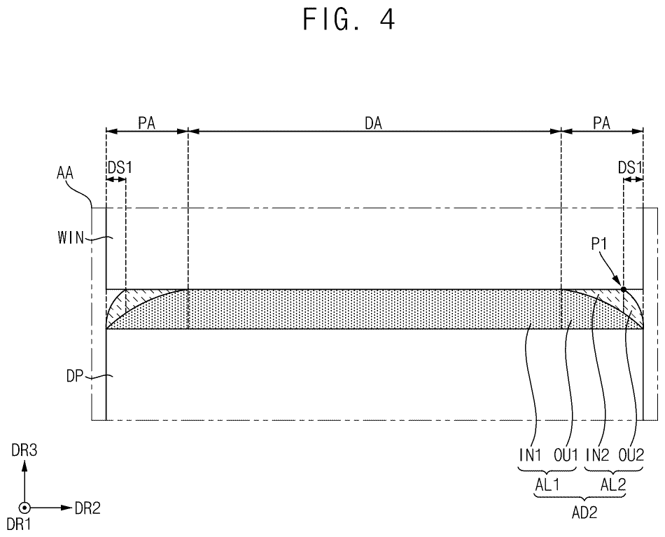

FIG. 4 is an enlarged view illustrating an area AA of FIG. 2.

FIG. 4 is an enlarged view illustrating the structure of the second adhesive member AD2 of FIG. 2 in more detail. Hereinafter, with reference to FIG. 4, the structure of the second adhesive member AD2 will be described in more detail.

Referring to FIG. 4, in an embodiment the second adhesive member AD2 may include a first adhesive layer AL1 and a second adhesive layer AL2.

The first adhesive layer AL1 may be disposed on the display panel DP (e.g., disposed directly thereon in the third direction DR3). In an embodiment, the first adhesive layer AL1 may be entirely disposed on the display panel DP. For example, the first adhesive layer AL1 may overlap entireties of the display area DA and the peripheral area PA (e.g., in the third direction DR3). However, embodiments of the present disclosure are not necessarily limited thereto. For example, in some embodiments the first adhesive layer AL1 may overlap and entirety of the display area DA (e.g., in the third direction DR3) and may overlap only a portion of the peripheral area PA (e.g., in the third direction DR3).

The first adhesive layer AL1 may include a first adhesive composition derived from a first resin composition. In an embodiment, the first adhesive composition may be obtained by photocuring the first resin composition. For example, in an embodiment the first adhesive layer AL1 may be formed by applying the first resin composition through an inkjet printing process and photocuring the applied first resin composition.

The first resin composition may be a liquid optical clear resin composition. In an embodiment, the first resin composition may include a monomer, a photoinitiator, and a contact angle regulator.

The monomer included in the first resin composition may include a crosslinking reactive group. In an embodiment, the monomer of the first resin composition may include an acrylate-based monomer. For example, in an embodiment the acrylate-based monomer may include 4-hydroxybutylacrylate (4-HBA), 2-ethylhexyl acrylate (2-EHA), tetrahydrofurfuryl acrylate (THF-A), 2-ethylhexyl diethylene glycol acrylate (EHDG-AT), and the like. These materials can be used alone or in combination with each other. However, the monomer included in the first resin composition is not necessarily limited thereto.

The photoinitiator included in the first resin composition may be activated by light in an ultraviolet range. For example, in an embodiment the photoinitiator may be activated by ultraviolet light having a central wavelength in a wavelength range of about 100 nm to about 400 nm. In an embodiment, the photoinitiator may include ethyl-(2,4,6-trimethylbenzoyl)-phenyl-phosphinate (TPO-L), bis-(2,4,6-trimethibenzoyl)-phenyl-phosphine oxide (Irgacure819), and the like. These materials can be used alone or in combination with each other. However, the photoinitiator included in the first resin composition is not necessarily limited thereto.

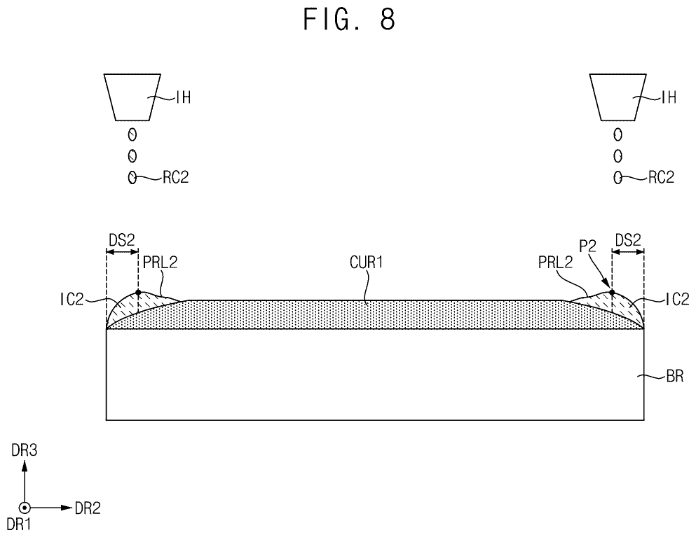

The contact angle regulator included in the first resin composition may be a material that increases the contact angle with respect to the second resin composition, which will be described later. The second resin composition may be a material applied to form the second adhesive layer AL2. In an embodiment, the contact angle regulator may adjust the contact angle of the surface of a cured layer so that the contact angle of the surface of the cured layer obtained by photocuring the first resin composition at a curing rate in a range of about 30% to about 50% with respect to the second resin composition is greater than or equal to about 30 degrees. For example, by adjusting the type and content of the contact angle regulator included in the first resin composition, the contact angle of the surface of the cured layer with respect to the second resin composition may be adjusted to greater than or equal to about 30 degrees. This will be described in more detail later with reference to FIG. 8.

In addition, the contact angle regulator included in the first resin composition may be a material that reduces the surface energy of the cured layer. For example, the contact angle regulator may adjust the surface energy of the cured layer so that the surface energy of the cured layer is less than or equal to about 45 mJ/m². For example, by adjusting the type and content of the contact angle regulator included in the first resin composition, the surface energy of the cured layer may be adjusted to be less than or equal to about 45 mJ/m². This will be described in more detail later with reference to FIG. 8.

In an embodiment, the type and content of the contact angle regulator may be set in consideration of other materials (e.g., the monomer, the photoinitiator, and the like) included in the first resin composition in addition to the contact angle regulator. In an embodiment, examples of materials that can be used as the contact angle regulator may include acrylic compounds, ether-based compounds, fluorine-based compounds, siloxane-based compounds, and cellulose acetate. These materials can be used alone or in combination with each other. However, the contact angle regulator included in the first resin composition is not necessarily limited thereto.

As a result, the first adhesive layer AL1 may include the contact angle adjusting agent. For example, even after the first adhesive layer AL1 is formed by photocuring the first resin composition, the contact angle regulator may remain in the first adhesive layer AL1.

As shown in FIG. 4, the first adhesive layer AL1 may include a first inner portion IN1 and a first outer portion OU1. In the first adhesive layer AL1, the first inner portion IN1 and the first outer portion OU1 may be divided according to a thickness distribution of the first adhesive layer AL1 (e.g., length in the third direction DR3). For example, the first inner portion IN1 and the first outer portion OU1 may be integral with each other and there may not be a break in the structure of the first adhesive layer AL1 between the first inner portion IN1 and the first outer portion OU1.

The first inner portion IN1 may be a portion in which a thickness of the first adhesive layer AL1 in the third direction DR3 is substantially constant on the display panel DP. For example, in the first inner portion IN1, the thickness of the first adhesive layer AL1 in the third direction DR3 on the display panel DP may be substantially uniform. For example, an upper surface of the first inner portion IN1 may be substantially flat. In an embodiment, the upper surface of the first inner portion IN1 may directly contact the window member WIN.

The first outer portion OU1 may be a portion in which a thickness of the first adhesive layer AL1 in the third direction DR3 significantly changes on the display panel DP. For example, in an embodiment the thickness of the first outer portion OU1 may gradually (e.g., continually) become thinner towards an edge of the first adhesive layer AL1. For example, the thickness of the first outer portion OU1 may gradually (e.g., continually) become thinner from a boundary with the first inner portion IN1 to the edge of the first adhesive layer AL1. Accordingly, an upper surface of the first outer portion OU1 may be inclined. In an embodiment, the upper surface of the first outer portion OU1 may directly contact the window member WIN at the boundary with the first inner portion IN1 and may be spaced apart from the window member WIN an increasing distance towards the edge of the first adhesive layer AL1 decreases.

As described above, when forming the first adhesive layer AL1 by applying and curing the first resin composition through an inkjet printing process, an inclined structure may be formed in a portion adjacent to the edge of the first adhesive layer AL1. Accordingly, the first outer portion OU1 having the thickness gradually (e.g., continually) becoming thinner towards the edge of the first adhesive layer AL1 may be defined.

In an embodiment, the first inner portion IN1 may overlap the display area DA (e.g., in the third direction DR3), and the first outer portion OU1 may overlap the peripheral area PA (e.g., in the third direction DR3). For example, the first outer portion OU1 may be disposed along the peripheral area PA and have a planar shape surrounding the display area DA. in an embodiment as shown in FIG. 4, the first outer portion OU1 is shown to overlap the entirety of the peripheral area PA (e.g., in the third direction DR3). However, embodiments of the present disclosure are not necessarily limited thereto. For example, the first outer portion OU1 may overlap only a portion of the peripheral area PA in some embodiments.

The second adhesive layer AL2 may be disposed on (e.g., disposed directly thereon) the first adhesive layer AL1. The second adhesive layer AL2 may be partially disposed on the first adhesive layer AL1. For example, the second adhesive layer AL2 may be selectively disposed on the first outer portion OU1 of the first adhesive layer AL1. For example, the second adhesive layer AL2 may overlap the first outer portion OU1 of the first adhesive layer AL1 in a plan view, and may be spaced apart from the first inner portion IN1 of the first adhesive layer AL1 in the plan view. For example, the second adhesive layer AL2 may only overlap the peripheral area PA (e.g., in the third direction DR3). For example, the second adhesive layer AL2 may be disposed along the peripheral area PA and have a planar shape surrounding the display area DA.

The second adhesive layer AL2 may fill at least a portion of an empty space defined between the first adhesive layer AL1 and the window member WIN by the first outer portion OU1 of the first adhesive layer AL1. Accordingly, the second adhesive layer AL2 may compensate for the inclined structure of the first adhesive layer AL1.

The second adhesive layer AL2 may include a second adhesive composition derived from a second resin composition. The second adhesive composition may be obtained by photocuring the second resin composition. For example, in an embodiment the second adhesive layer AL2 may be formed by applying the second resin composition through an inkjet printing process and photocuring the applied second resin composition.

In an embodiment, the second resin composition may be a liquid optical clear resin composition. For example, in an embodiment, the second resin composition may include a monomer and a photoinitiator.

In an embodiment, the description of the monomer and the photoinitiator included in the second resin composition may be the same as the description of the monomer and the photoinitiator included in the first resin composition. Therefore, the corresponding description is omitted for economy of description.

In an embodiment, the first resin composition and the second resin composition may be the same as each other. For example, in an embodiment the type and content of the monomer included in the first resin composition may be the same as the type and content of the monomer included in the second resin composition, the type and content of the photoinitiator included in the second resin composition may be the same as the type and content of the photoinitiator included in the second resin composition, and the second resin composition may also include the same content of the contact angle regulator included in the first resin composition.

In this embodiment, the second adhesive layer AL2 may include the contact angle regulator. For example, even after the second adhesive layer AL2 is formed by photocuring the second resin composition, the contact angle regulator may remain in the second adhesive layer AL2. In an embodiment in which the first resin composition and the second resin composition are the same as each other, the ease of forming the second adhesive member AD2 may be increased.

As shown in FIG. 4, the second adhesive layer AL2 may include a second inner portion IN2 and a second outer portion OU2. In the second adhesive layer AL2, the second inner portion IN2 and the second outer portion OU2 may be divided according to the thickness distribution of the second adhesive layer AL2 (e.g., length in the third direction DR3). For example, the second inner portion IN2 and the second outer portion OU2 may be integral with each other and the structure of the second adhesive layer AL2 may not include a break between the second inner portion IN2 and the second outer portion OU2.

The second inner portion IN2 may be a portion in which the thickness of the second adhesive layer AL2 in the third direction DR3 significantly changes on the first adhesive layer AL1. For example, the thickness of the second inner portion IN2 may gradually (e.g., continually) increase towards an edge of the second adhesive layer AL2. For example, an upper surface of the second inner portion IN2 may be substantially flat, and a lower surface of the second inner portion IN2 may be inclined along the upper surface of the first outer portion OU1 of the first adhesive layer AL1. Accordingly, the thickness of the second inner portion IN2 may gradually (e.g., continually) increase towards the edge of the second adhesive layer AL2.

The second outer portion OU2 may be a portion in which the thickness of the second adhesive layer AL2 in the third direction DR3 significantly changes on the first adhesive layer AL1. For example, the thickness of the second outer portion OU2 may gradually (e.g., continually) become thinner towards the edge of the second adhesive layer AL2. For example, the thickness of the second outer portion OU2 may gradually (e.g., continually) become thinner from a boundary with the second inner portion IN2 to the edge of the second adhesive layer AL2. Accordingly, an upper surface of the second outer portion OU2 may be inclined.

For example, as described above, when forming the second adhesive layer AL2 by applying and curing the second resin composition through an inkjet printing process, an inclined structure may be formed on a portion adjacent to the edge of the second adhesive layer AL2. Accordingly, the second outer portion OU2 having the thickness gradually (e.g., continually) becoming thinner towards the edge of the second adhesive layer AL2 may be defined.

In an embodiment, a first length DS1 in a horizontal direction from a first point P1 where the second outer portion OU2 starts to the edge of the second adhesive layer AL2 may be less than or equal to about 1 mm. For example, the first length DS1 in the horizontal direction from the boundary between the second inner portion IN2 and the second outer portion OU2 to the edge of the second adhesive layer AL2 may be less than or equal to about 1 mm. In this specification, the horizontal direction may be a concept including all of the second direction DR2, a direction opposite to the second direction DR2, the first direction DR1, and the direction opposite to the first direction DR1. For example, the horizontal direction may be any one of the second direction DR2, the opposite direction of the second direction DR2, the first direction DR1, and the direction opposite to the first direction DR1. In an embodiment, the first length DS1 may be in a range of about 0.005 mm to about 1 mm.

As the second adhesive layer AL2 includes the second outer portion OU2 having the inclined structure, a predetermined empty space may occur between the second outer portion OU2 and the window member WIN. Accordingly, when the first length DS1 of the second outer portion OU2 becomes longer, the dead space of the display device DD may increase. In addition, due to the inclined structure of the second outer portion OU2, when the first length DS1 of the second outer portion OU2 becomes longer, the second outer portion OU2 may be visible from the outside and the visibility of the display device DD may deteriorate.

In the second adhesive member AD2 according to an embodiment of the present disclosure, the second adhesive layer AL2 may be formed by photocuring the second resin composition. In the process of manufacturing the second adhesive layer AL2, the second resin composition may be applied to the surface of the cured layer, and the contact angle of the surface of the cured layer with respect to the second resin composition may be greater than or equal to about 30 degrees. Accordingly, in a preliminary layer formed by applying the second resin composition on the surface of the cured layer, a length in the horizontal direction of the inclined portion having the thickness gradually (e.g., continually) becomes thinner towards the edge of the preliminary layer may be reduced. As a result, the length of the second outer portion OU2 of the second adhesive layer AL2 derived from the preliminary layer in the horizontal direction may be reduced. For example, as described above, the first length DS1 in the horizontal direction from the first point P1 where the second outer portion OU2 starts to the edge of the second adhesive layer AL2 may be less than or equal to about 1 mm. Accordingly, the second outer portion OU2 may not be visible from the outside, and visibility of the display device DD may be increased. In addition, the dead space of the display device DD may be reduced.

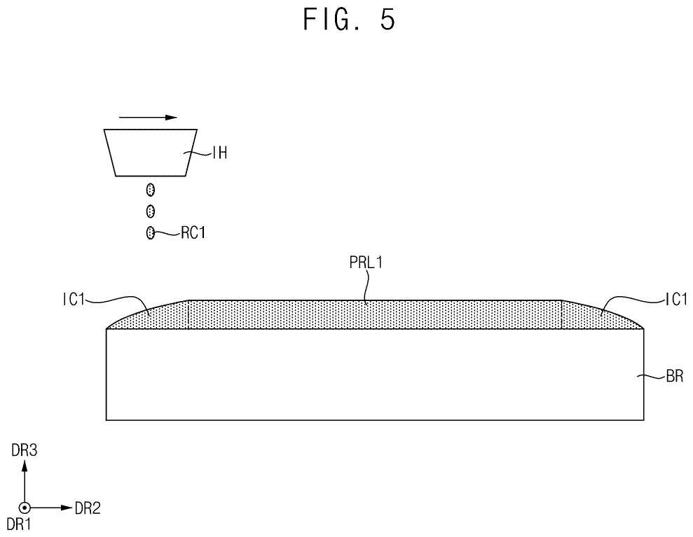

FIGS. 5, 6, 7, 8, 9, 11, and 12 are views illustrating a method of manufacturing a second adhesive member of FIG. 4.

Hereinafter, the method of manufacturing the second adhesive member AD2 will be described in more detail with reference to FIGS. 5, 6, 7, 8, 9, 11, and 12.

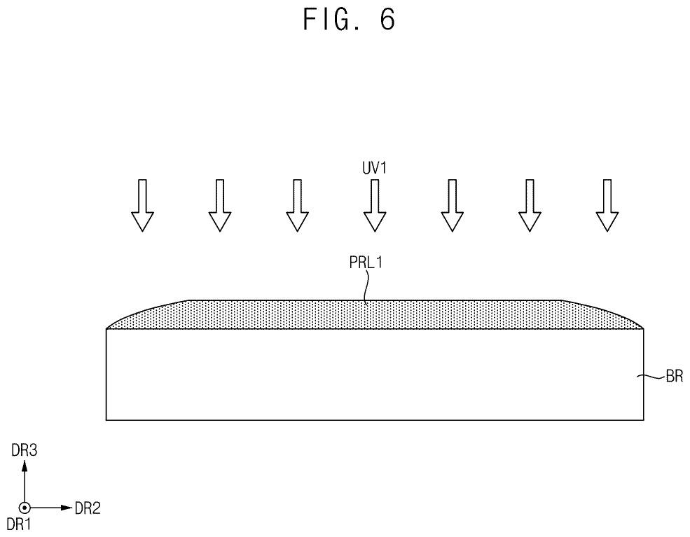

In the following description referring to FIGS. 6, 7, 8, 9, 11, and 12, a base layer on which the second adhesive member AD2 is formed is expressed as a base material BR. For example, in an embodiment in which a process of forming the second adhesive member AD2 is performed directly on the display panel DP of FIG. 4, the base material BR may be the display panel DP of FIG. 4. However, embodiments of the present disclosure are not necessarily limited thereto. For example, in an embodiment in which the polarizing layer is disposed on the display panel DP and a process of forming the second adhesive member AD2 is performed on the polarizing layer, the base material BR may be the polarizing layer.

Referring to FIG. 5, a first preliminary layer PRL1 may be formed by applying a first resin composition RC1 on the base material BR. For example, the first resin composition RC1 may be applied on (e.g., disposed directly thereon in the third direction DR3) an entirety of the base material BR.

As described above, the first resin composition RC1 may be an optical clear resin composition. For example, the first resin composition RC1 may be provided in liquid form. In an embodiment, the first resin composition RC1 may include the monomer and the photoinitiator. Since the description of the monomer and the photoinitiator is the same as the description referring to FIG. 4, the corresponding description will be omitted for economy of explanation.

In an embodiment, an inkjet printing process (e.g., a first inkjet printing process) may be used as a method of applying the first resin composition RC1. For example, the first resin composition RC1 may be provided through nozzles of the inkjet head IH. When applying the first resin composition RC1 by the inkjet printing process, the first resin composition RC1 should have a low viscosity for excellent jettability. For example, in an embodiment the first resin composition RC1 may have a viscosity in a range of about 5 cP to about 40 cP measured at a temperature of about 25° C. If the viscosity of the first resin composition RC1 is less than 5 cP when applying the first resin composition RC1 on the base material BR, a problem may occur in which the first resin composition RC1 flows out from the end of the base material BR. In addition, if the viscosity of the first resin composition RC1 exceeds 40 cP, application by the inkjet printing process may become difficult due to the high viscosity.

As shown in FIG. 5, the first preliminary layer PRL1 may have a first inclined portion IC1 having a thickness in the third direction DR3 that significantly changes on the substrate BR. The thickness of the first inclined portion IC1 may gradually (e.g., continually) become thinner towards the edge of the first preliminary layer PRL1. Accordingly, the upper surface of the first inclined portion IC1 may be inclined. The first inclined portion IC1 may form the first outer portion OU1 of FIG. 4 through subsequent curing processes.

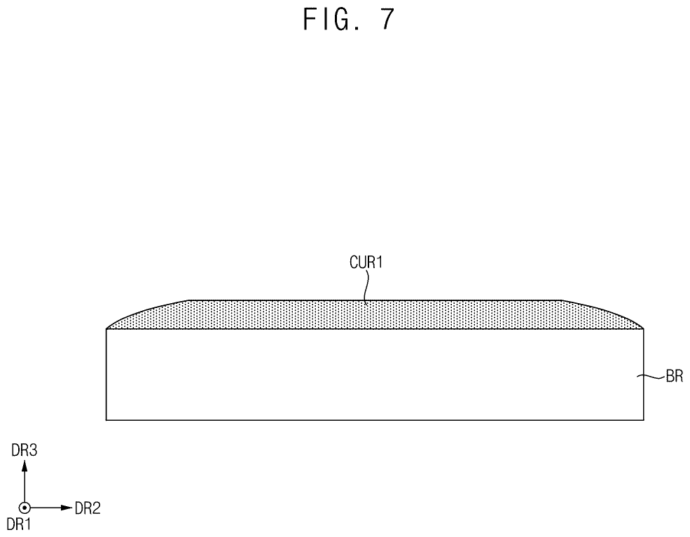

Referring to FIGS. 6 and 7, the first preliminary layer PRL1 may be photocured to form a first cured layer CUR1. For example, as shown in FIG. 6, a first light UV1 may be irradiated to an entirety of the surface of the first preliminary layer PRL1, and the first preliminary layer PRL1 including the photoinitiator may be cured by the first light UV1. In an embodiment, the first light UV1 may be ultraviolet light.

Accordingly, as shown in FIG. 7, the first hardened layer CUR1 may be formed. In an embodiment, the curing rate of the first cured layer CUR1 formed by irradiating the first light UV1 to the first preliminary layer PRL1 may be in a range of about 35% to about 50%. For example, the curing rate of the first cured layer CUR1 may be in a range of about 35% to about 45%, such as about 40%. For example, the first cured layer CUR1 may be in a pre-cured state in which the first preliminary layer PRL1 is partially cured. The first cured layer CUR1 may not be in a fully cured state of the first preliminary layer PRL1.

The curing rate may be calculated based on the amount of crosslinking reactor (e.g., crosslinking reactor of the monomer) in the first preliminary layer PRL1 before curing by the first light UV1 and the amount of crosslinking reactor in the first cured layer CUR1 after curing by the first light UV1. For example, in an embodiment the curing rate of the first cured layer CUR1 may satisfy Equation 1 below. Equation 1 below may be an equation regarding the absorption amount of the crosslinking reactor measured by Fourier-transform infrared spectroscopy (FT-IR) before and after provision of the first light UV1.

Z=[(X−Y)/X]×100% <Equation 1>

In Equation 1, X may be the absorption amount of the crosslinking reactor measured for the first preliminary layer PRL1, Y may be the absorption amount of the crosslinking reactor measured for the first cured layer UR1, and Z may be the curing rate. For example, when the crosslinking reactor does not exist in the first cured layer CUR1, the curing rate may be 100%. In contrast, when the crosslinking reactor remains in the first cured layer CUR1, the curing rate may be 0%.

Referring further to FIG. 8, in an embodiment a second preliminary layer PRL2 may be formed by applying a second resin composition RC2 on the first cured layer CUR1. For example, in an embodiment the second resin composition RC2 may be applied on a portion of the first cured layer CUR1. For example, in an embodiment the second resin composition RC2 may be selectively applied on a portion of the first cured layer CUR1 in which the first inclined portion IC1 is cured by the first light UV1.

As described above, the second resin composition RC2 may be an optical clear resin composition. For example, the second resin composition RC2 may be provided in liquid form. In an embodiment, the second resin composition RC2 may include the monomer and the photoinitiator. Since the description of the monomer and the photoinitiator is the same as the description referring to FIG. 4, the corresponding description will be omitted for economy of explanation.

In an embodiment, the inkjet printing process (e.g., a second inkjet printing process) may be used as a method of applying the second resin composition RC2. For example, the second resin composition RC2 may be provided through nozzles of the inkjet head IH. When applying the second resin composition RC2 by the inkjet printing process, the second resin composition RC2 should have a low viscosity for excellent jettability. For example, in an embodiment the second resin composition RC2 may have a viscosity in a range of about 5 cP to about 40 cP measured at a temperature of about 25° C. If the viscosity of the second resin composition RC2 is less than 5 cP, when the second resin composition RC2 is applied on the first cured layer CUR1, a problem may occur in which the second resin composition RC2 flows out from the end of the first cured layer CUR1. In addition, if the viscosity of the second resin composition RC2 exceeds 40 cP, application by the inkjet printing process may become difficult due to the high viscosity.

As shown in FIG. 8, the second preliminary layer PRL2 may have a second inclined portion IC2 having a thickness in the third direction DR3 that significantly changes on the first hardened layer CUR1. For example, in an embodiment the thickness of the second inclined portion IC2 may gradually (e.g., continually) become thinner towards the edge of the second preliminary layer PRL2. Accordingly, the upper surface of the second inclined portion IC2 may be inclined. The second inclined portion IC2 may form the second outer portion OU2 of FIG. 4 through subsequent curing processes.

As described above with reference to FIG. 4, to adjust the first length DS1 of the second outer portion OU2 of the second adhesive layer AL2 formed from the second inclined portion IC2 to be small, the second length DS2 of the second inclined portion IC2 in the horizontal direction may be adjusted to be small. In addition, to adjust the second length DS2 of the second inclined portion IC2 to be small, the contact angle of the surface of the first cured layer CUR1 with respect to the second resin composition RC2 may be adjusted to be greater than a certain value.

In the present disclosure, the contact angle and surface energy of the surface of the first cured layer CUR1 with respect to the second resin composition RC2 may be adjusted by adjusting the composition of the first resin composition RC1.

For example, in an embodiment the first resin composition RC1 may further include the contact angle regulator. The contact angle regulator included in the first resin composition RC1 may be a material that increases the contact angle of the surface of the first cured layer CUR1 with respect to the second resin composition RC2. For example, in an embodiment the contact angle regulator may adjust the contact angle of the surface of the first cured layer CUR1 so that the contact angle of the surface of the first cured layer CUR1 with respect to the second resin composition RC2 is greater than or equal to about 30 degrees. For example, by adjusting the type and content of the contact angle regulator included in the first resin composition RC1, the contact angle of the surface of the first cured layer CUR1 with respect to the second resin composition RC2 may be adjusted to be greater than or equal to about 30 degrees.

If the contact angle of the surface of the first cured layer CUR1 with respect to the second resin composition RC2 is less than 30 degrees, a second length DS2 of the second inclined portion IC2 of the second preliminary layer PRL2 may be increased, and accordingly, the first length DS1 of the second outer portion OU2 of FIG. 4 formed from the second inclined portion IC2 may be increased. For example, if the contact angle of the surface of the first cured layer CUR1 with respect to the second resin composition RC2 is less than 30 degrees, the first length DS1 of the second outer portion OU2 of FIG. 4 may exceed about 1 mm. Accordingly, the second outer portion OU2 may be visible, and the visibility of the display device DD may be reduced and the dead space of the display device DD may increase.

In an embodiment of the present disclosure, the contact angle of the surface of the first cured layer CUR1 with respect to the second resin composition RC2 may be greater than or equal to about 30 degrees, and accordingly, the first length DS1 of the second outer portion OU2 of FIG. 4 may be less than or equal to about 1 mm. Accordingly, the second outer portion OU2 may not be visible from the outside by the user, and visibility of the display device DD may be increased. In addition, the dead space of the display device DD may be reduced.

In an embodiment, the contact angle of the surface of the first cured layer CUR1 with respect to the second resin composition RC2 may be in a range of about 30 degrees to about 50 degrees. For example, in an embodiment in which the first resin composition RC1 and the second resin composition RC2 are the same as each other, the contact angle of the surface of the first cured layer CUR1 with respect to the second resin composition RC may not exceed 50 degrees. However, embodiments of the present disclosure are not necessarily limited thereto.

In addition, the contact angle regulator included in the first resin composition RC1 may be a material that reduces the surface energy of the first cured layer CUR1. For example, in an embodiment the contact angle regulator may adjust the surface energy of the first cured layer CUR1 so that the surface energy of the first cured layer CUR1 is less than or equal to about 45 mJ/m². For example, by adjusting the type and content of the contact angle regulator included in the first resin composition RC1, the surface energy of the first cured layer CUR1 may be adjusted to less than or equal to about 45 mJ/m².

When the surface energy of the first cured layer CUR1 exceeds 45 mJ/m², the contact angle of the second resin composition RC2 with respect to the surface of the first cured layer CUR1 may be reduced. For example, the contact angle of the surface of the first cured layer CUR1 with respect to the second resin composition RC2 may be less than about 30 degrees. Accordingly, the second length DS2 of the second inclined portion IC2 of the second preliminary layer PRL2 may be increased, and accordingly, the first length DS1 of the second outer portion OU2 of FIG. 4 formed from the second inclined portion IC2 may be increased. As a result, if the surface energy of the first cured layer CUR1 exceeds 45 mJ/m², the first length DS1 of the second outer portion OU2 of FIG. 4 may exceed about 1 mm. Accordingly, since the second outer portion OU2 is visible, visibility of the display device DD may be reduced and the dead space of the display device DD may increase.

For example, in an embodiment the surface energy of the first cured layer CUR1 may be in a range of about 20 mJ/m² to about 45 mJ/m². If the surface energy of the first cured layer CUR1 is less than about 20 mJ/m², the second preliminary layer PRL2 may not be sufficiently applied on the first cured layer CUR1. Therefore, in an embodiment the surface energy of the first hardened layer CUR1 may be greater than or equal to about 20 mJ/m². For example, in an embodiment the surface energy of the first cured layer CUR1 may be in a range of about 25 mJ/m² to about 35 mJ/m².

In an embodiment, even when the contact angle of the surface of the first cured layer CUR1 with respect to the second resin composition RC2 is greater than or equal to about 30 degrees, the viscosity of the first resin composition RC1 may satisfy the above-mentioned range of about 5 cP to about 40 cP. For example, in an embodiment the contact angle regulator may be a material that adjusts the contact angle of the surface of the first cured layer CUR1 with respect to the second resin composition RC2 to be greater than or equal to about 30 degrees while maintaining the viscosity of the first resin composition RC1 within the range of about 5 cP to about 40 Cp. Accordingly, in the inkjet printing process, the jettability of the first resin composition RC1 may not deteriorate, and the problem of processability deterioration due to an increase in application difficulty may not occur.

In an embodiment, the type and content of the contact angle regulator may be set in consideration of other materials (e.g., the monomer, the photoinitiator, and the like) included in the first resin composition RC1 in addition to the contact angle regulator. In an embodiment, examples of the contact angle regulator may include acrylic compounds, ether compounds, fluorine compounds, siloxane compounds, and cellulose acetate. These materials can be used alone or in combination with each other. However, embodiments of the present disclosure are not necessarily limited thereto.

In an embodiment, the contact angle regulator may include polyalkyl vinyl ether, fluorine-based surfactant, di-methyl polysiloxane, methyl phenyl polysiloxane, organic modified polysiloxane, cellulose acetate butylate, and the like. These materials can be used alone or in combination with each other. However, embodiments of the present disclosure are not necessarily limited thereto.

However, if the physical properties of the first resin composition RC1 can be adjusted to satisfy the contact angle of the surface of the first cured layer CUR1 with respect to the second resin composition RC2, the surface energy of the first cured layer CUR1, and the viscosity of the first resin composition RC1 are within the above-mentioned range, the type of the contact angle regulator included in the first resin composition RC1 is not necessarily limited thereto.

As shown in FIG. 8, the second length DS2 of the second inclined portion IC2 of the second preliminary layer PRL2 in the horizontal direction may be less than or equal to about 2 mm. For example, the second length DS2 in the horizontal direction from a second point P2 where the second inclined portion IC2 starts to the edge of the second preliminary layer PRL2 may be less than or equal to about 2 mm. In an embodiment, the second length DS2 may be in a range of about 0.01 mm to about 2 mm.

For example, in the present disclosure, the contact angle of the surface of the first cured layer CUR1 with respect to the second resin composition RC2 may be greater than or equal to about 30 degrees, and accordingly, the second length DS2 of the second inclined portion IC2 of the second preliminary layer PRL2 in the horizontal direction may be adjusted to less than or equal to about 2 mm. Accordingly, the second length DS2 of the second outer portion OU2 of FIG. 4 formed through subsequent curing processes may be less than or equal to about 1 mm. Accordingly, visibility of the display device DD may be increased and the dead space of the display device DD may be reduced.

In an embodiment, the first resin composition RC1 may be the same as the second resin composition RC2. For example, the second resin composition RC2 may also include the contact angle regulator. In an embodiment, the same resin composition may be used in the steps of forming the first preliminary layer PRL1 and the step of forming the second preliminary layer PRL2. Accordingly, the ease of forming the second adhesive member AD2 may be increased.

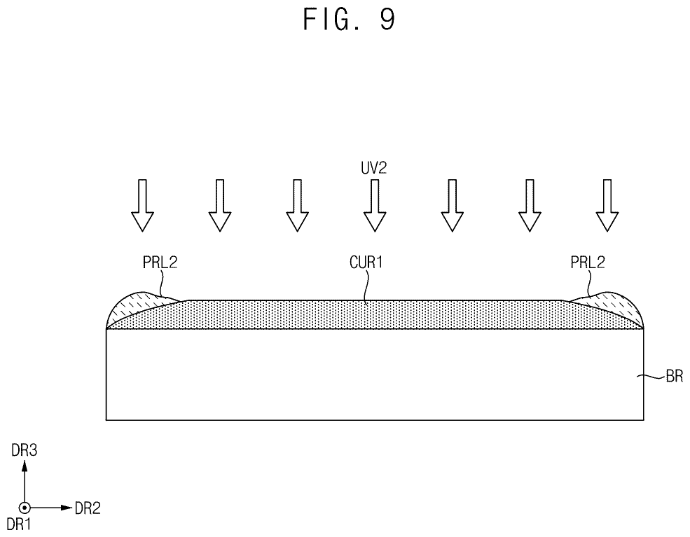

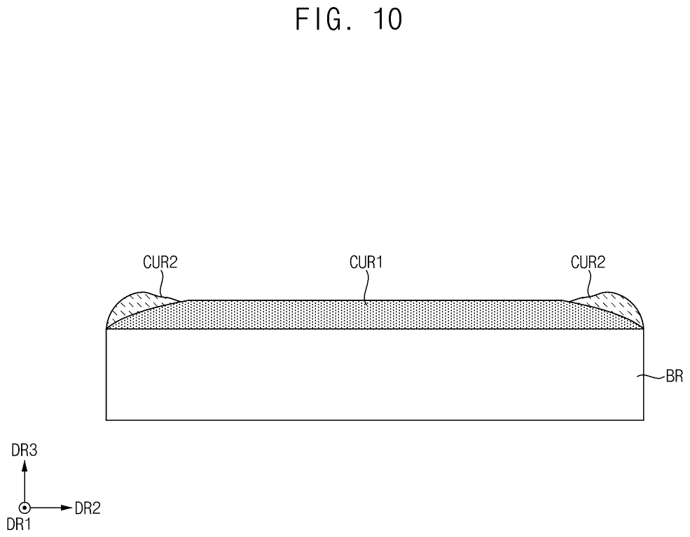

Referring to FIGS. 9 and 10, the second preliminary layer PRL2 may be photocured to form a second cured layer CUR2. For example, as shown in FIG. 9, a second light UV2 may be irradiated to an entire surface of the second preliminary layer PRL2, and the second preliminary layer PRL2 including the photoinitiator may be cured by the second light UV2. In an embodiment, the second light UV2 may be ultraviolet light.

Accordingly, as shown in FIG. 10, the second hardened layer CUR2 may be formed. In an embodiment, the second cured layer CUR2 may be in a pre-cured state in which the second preliminary layer PRL2 is partially cured. For example, the second cured layer CUR2 may not be a fully cured state of the second preliminary layer PRL2.

In an embodiment, in the process of photocuring the second preliminary layer PRL2, the first cured layer CUR1 may be cured together with the second light UV2. For example, the curing rate of the first cured layer CUR1 may increase after the second cured layer CUR2 is formed, compared to before the second cured layer CUR2 is formed.

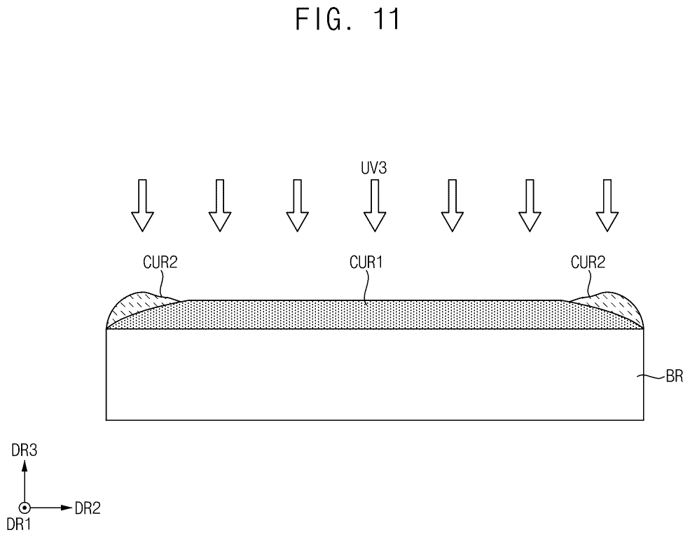

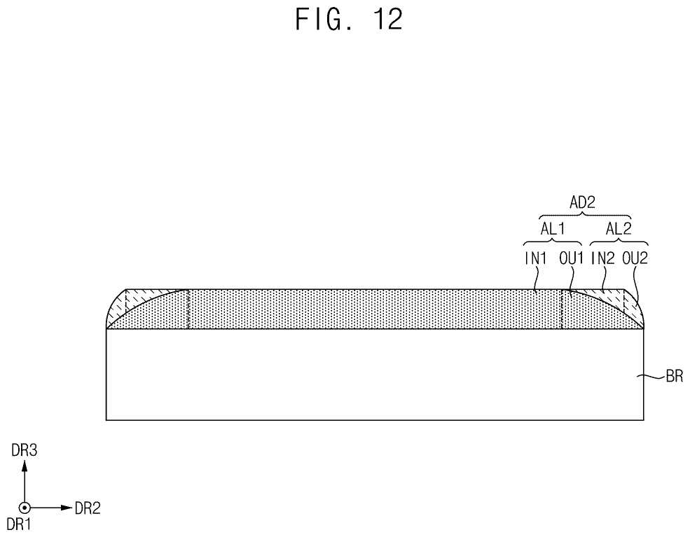

Referring to FIGS. 11 and 12, the first cured layer CUR1 and the second cured layer CUR2 may be photocured to form the first adhesive layer AL1 and the second adhesive layer AL2. In an embodiment, the first cured layer CUR1 in a pre-cured state may be photocured to form the first adhesive layer AL1 in a substantially fully cured state. In addition, the second cured layer CUR2 in a pre-cured state may be photocured to form the second adhesive layer AL2 in a substantially fully cured state.

For example, as shown in FIG. 11, a third light UV3 may be irradiated to the entire surface of the first cured layer CUR1 and the second cured layer CUR2, and the first cured layer CUR1 and the second cured layer CUR2 including the photoinitiator may be fully cured by the third light UV3. In an embodiment, the third light UV3 may be ultraviolet light.

As a result, as shown in FIG. 12, the first inclined portion IC1 of FIG. 5 may be cured through a plurality of curing processes to form the first outer portion OU1. In addition, the second inclined portion IC2 of FIG. 8 may be cured through a plurality of curing processes to form the second outer portion OU2. For example, the first adhesive layer AL1 may include the first inner portion IN1 and the first outer portion OU1, and the second adhesive layer AL2 may include the second inner portion IN2 and the second outer portion OU2.

In the method of manufacturing the second adhesive member AD2 according to an embodiment of the present disclosure, the second adhesive member AD2 may be formed to include the first adhesive layer AL1 and the second adhesive layer AL2 disposed on (e.g., disposed directly thereon) the first adhesive layer AL1. The second adhesive layer AL2 may be formed by forming a preliminary layer by applying a second resin composition on a cured layer in which the first resin composition has been cured at a curing rate in a range of about 35% to about 50%, and photocuring the preliminary layer. In addition, a contact angle of a surface of the cured layer with respect to the second resin composition may be greater than or equal to about 30 degrees.

Accordingly, in the preliminary layer, a length in the horizontal direction of an inclined portion having a thickness gradually (e.g., continually) becoming thinner towards an edge of the preliminary layer may be reduced. As a result, the length (i.e., the first length DS1 of FIG. 4) of the inclined structure (e.g., the second outer portion OU2 of FIG. 4) of the second adhesive layer AL2 derived from the preliminary layer in the horizontal direction may be reduced. For example, the length of the inclined structure of the second adhesive layer AL2 in the horizontal direction may be less than or equal to about 1 mm. Accordingly, in the display device DD including the second adhesive member AD2, the inclined structure of the second adhesive layer AL2 may not be visible from the outside, thereby increasing visibility of the display device DD. In addition, the dead space of the display device DD may be reduced.

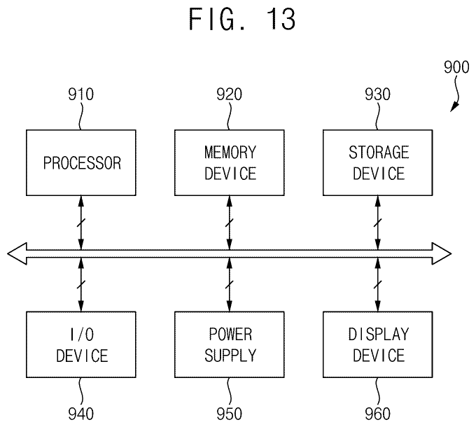

FIG. 13 is a block diagram illustrating an electronic device according to an embodiment of the present disclosure.

Referring to FIG. 13, in an embodiment, an electronic device 900 may include a processor 910, a memory device 920, a storage device 930, an input/output device 940, a power supply 950, and a display device 960. In this case, the display device 960 may correspond to the display device DD described with reference to FIGS. 1, 2, and 3. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

Embodiments of the present disclosure can be applied to display devices and electronic devices including the same. For example, the present disclosure is applicable to various display devices such as display devices for vehicles, ships and aircraft, portable communication devices, display devices for exhibition or information transmission, medical display devices, and the like.

The foregoing is illustrative of non-limiting embodiments and is not to be construed as limiting thereof. Although a few embodiments have been described, those skilled in the art will readily appreciate that many modifications are possible in the described embodiments without materially departing from the novel teachings and advantages of the present disclosure. Accordingly, all such modifications are intended to be included within the scope of embodiments of the present disclosure. Therefore, it is to be understood that the foregoing is illustrative of various non-limiting embodiments and is not to be construed as limited to the specific described embodiments, and that modifications to the described embodiments, as well as other embodiments, are intended to be included within the scope of the present disclosure.

What is claimed is:

1. A method of manufacturing an adhesive member, the method comprising:
applying a first resin composition on a base material to form a first preliminary layer;
photocuring the first preliminary layer to form a first cured layer;
applying a second resin composition on the first cured layer to form a second preliminary layer; and
photocuring the second preliminary layer to form a second cured layer,
wherein a contact angle of a surface of the first cured layer with respect to the second resin composition is greater than or equal to about 30 degrees.

2. The method of claim 1, wherein a surface energy of the first cured layer is less than or equal to about 45 mJ/m².

3. The method of claim 1, wherein a viscosity of the first resin composition is in a range of about 5 cP to about 40 cP.

4. The method of claim 1, wherein:
the second preliminary layer has an inclined portion having a thickness becoming thinner towards an edge of the second preliminary layer; and
a length in a horizontal direction from a point where the inclined portion of the second preliminary layer starts to the edge of the second preliminary layer is less than or equal to about 2 mm.

5. The method of claim 1, wherein:
the first resin composition is first applied on the base material through an inkjet printing process; and
the second resin composition is subsequently applied on the first cured layer through the inkjet printing process.

6. The method of claim 1, wherein in the forming of the adhesive member:
the first cured layer is cured to form a first adhesive layer disposed on the base material; and
the second cured layer is cured to form a second adhesive layer selectively disposed on an outer portion of the first adhesive layer.

7. The method of claim 1, wherein in the forming of the first cured layer, a curing rate of the first cured layer by photocuring is in a range of about 35% to about 50%.

8. The method of claim 1, wherein the first resin composition includes a contact angle regulator.

9. The method of claim 1, wherein the first resin composition and the second resin composition are a same composition as each other.

10. An adhesive member comprising:
a first adhesive layer including a first adhesive composition derived from a first resin composition that includes a photoinitiator; and
a second adhesive layer disposed on the first adhesive layer, the second adhesive layer includes a second adhesive composition derived from a second resin composition that includes a photoinitiator,
wherein a contact angle of a surface of a cured layer obtained by photocuring the first resin composition at a curing rate in a range of about 35% to about 50% with respect to the second resin composition is greater than or equal to about 30 degrees.

11. The adhesive member of claim 10, wherein a surface energy of the cured layer is less than or equal to about 45 mJ/m².

12. The adhesive member of claim 10, wherein:
the first adhesive layer has a first outer portion having a thickness that becomes thinner towards an edge of the first adhesive layer;
the second adhesive layer has a second outer portion having a thickness that becomes thinner towards an edge of the second adhesive layer;
the second adhesive layer is selectively disposed on the first outer portion of the first adhesive layer; and
a length in a horizontal direction from a point where the second outer portion of the second adhesive layer starts to the edge of the second adhesive layer is less than or equal to about 1 mm.

13. The adhesive member of claim 10, wherein the first adhesive layer includes a contact angle regulator.

14. A display device comprising:
a display panel including a display area and a peripheral area surrounding the display area;
a window member disposed on the display panel;
a first adhesive layer disposed between the display panel and the window member, the first adhesive layer overlapping the display area and the peripheral area, the first adhesive layer including a first adhesive composition derived from a first resin composition including a photoinitiator; and
a second adhesive layer disposed on the first adhesive layer, the second adhesive layer overlaps the peripheral area, the second adhesive layer including a second adhesive composition derived from a second resin composition including a photoinitiator,
wherein a contact angle of a surface of a cured layer obtained by photocuring the first resin composition at a curing rate in a range of about 35% to about 50% with respect to the second resin composition is greater than or equal to about 30 degrees.

15. The display device of claim 14, wherein a surface energy of the cured layer is less than or equal to about 45 mJ/m².

16. The display device of claim 14, wherein:
the first adhesive layer has a first outer portion having a thickness becoming thinner towards an edge of the first adhesive layer; and
the second adhesive layer has a second outer portion having a thickness becoming thinner towards an edge of the second adhesive layer.

17. The display device of claim 16, wherein a length in a horizontal direction from a point where the second outer portion of the second adhesive layer starts to the edge of the second adhesive layer is less than or equal to about 1 mm.

18. The display device of claim 16, wherein the second adhesive layer is selectively disposed on the first outer portion of the first adhesive layer.

19. The display device of claim 14, wherein the first adhesive layer includes a contact angle regulator.

20. The display device of claim 14, wherein the first resin composition and the second resin composition are a same composition as each other.

21. An electronic device comprising:
a display device; and
a processor which controls the display device,
wherein display device include:
a display panel including a display area and a peripheral area surrounding the display area;
a window member disposed on the display panel;
a first adhesive layer disposed between the display panel and the window member, the first adhesive layer overlapping the display area and the peripheral area, the first adhesive layer including a first adhesive composition derived from a first resin composition including a photoinitiator; and
a second adhesive layer disposed on the first adhesive layer, the second adhesive layer overlaps the peripheral area, the second adhesive layer including a second adhesive composition derived from a second resin composition including a photoinitiator, and
wherein a contact angle of a surface of a cured layer obtained by photocuring the first resin composition at a curing rate in a range of about 35% to about 50% with respect to the second resin composition is greater than or equal to about 30 degrees.
